(19) United States
(12) Patent Application Publication
(10) Pub. No.: US 2025/0183095 A1
(43) Pub. Date: Jun. 5, 2025

(54) METHOD OF FABRICATING OXIDE FILM WITH UNIFORM THICKNESS

(71) Applicant: DB HiTek Co., Ltd., Bucheon-si (KR)

(72) Inventor: Jong Won SUN, Icheon-si (KR)

(21) Appl. No.: 18/415,775

(22) Filed: Jan. 18, 2024

(30) Foreign Application Priority Data
Dec. 1, 2023 (KR) 10-2023-0172081

(51) Int. Cl. H01L 21/762; H01L 21/265; H01L 21/308; H01L 21/324

(52) U.S. Cl. CPC H01L 21/76237; H01L 21/26533; H01L 21/308; H01L 21/324

(57) ABSTRACT

Proposed is a method of fabricating an oxide film with a uniform thickness, in which when forming an oxide film in a trench for a device isolation layer and/or on a silicon substrate at a position adjacent to the trench, the silicon substrate is locally amorphized at positions corresponding to corners, inner sidewalls, and/or a bottom surface of the trench and then oxidized so that the oxide film in the trench and/or adjacent to the trench is formed with a substantially uniform thickness.

### CROSS-REFERENCE TO RELATED APPLICATION

The present application claims priority to Korean Patent Application No. 10-2023-0172081, filed Dec. 1, 2023, the entire contents of which are incorporated herein for all purposes by this reference.

### BACKGROUND OF THE INVENTION

### Field of the Invention

The present disclosure relates generally to a method of fabricating an oxide film with a uniform thickness. More particularly, the present disclosure relates to a method of fabricating an oxide film with a uniform thickness, in which when forming an oxide film in a trench for a device isolation layer and/or on a silicon substrate at a position adjacent to the trench, the silicon substrate is amorphized at positions corresponding to corners, inner sidewalls, and/or a bottom surface of the trench and then oxidized so that the oxide film in the trench and/or adjacent to the trench is formed with a substantially uniform thickness.

### Description of the Related Art

Recently, with integration of semiconductor devices, shallow trench isolation (STI) structures have been used to improve the device isolation characteristics of the semiconductor devices. An STI structure is a technology that forms a device isolation layer by forming a trench with a predetermined depth on a semiconductor substrate, depositing an oxide film on the trench by a chemical vapor deposition (CVD) process, and etching the unnecessary oxide film through a chemical mechanical polishing (CMP) process. The STI structure is mostly used in high-integration semiconductor devices due to its superior device isolation characteristics and a relatively small occupied area compared to a conventional local oxidation of silicon (LOCOS) structure, which forms a device isolation layer by selectively growing a thick oxide film on a semiconductor substrate.

FIG. 1 is a sectional view illustrating problems of the related art that occur when forming a gate oxide film after forming a device isolation layer.

Hereinafter, the problems that arise when forming a device isolation layer of a conventional STI structure will be briefly described with reference to the accompanying drawings.

The formation of the device isolation layer is achieved is as follows. First, a trench 940 is formed by etching a silicon substrate 901 to a predetermined depth, and then an insulating film is deposited on the substrate 901 and in the trench 940. Thereafter, a CMP process and a cleaning process are performed to complete a device isolation layer 910. Referring to FIG. 1, during the cleaning process for forming the device isolation layer 910, edges 911 of the device isolation layer 910 may be excessively etched, resulting in divots 920.

In this state in which the divots 920 are generated, for example, when forming a gate oxide film 930 on the substrate 901, the thickness of the gate oxide film 930 may become uneven on corners 931 of the gate oxide film 930 due to the divots 920. This is called a thinning phenomenon. In detail, the thickness of the gate oxide film 930 formed on the silicon substrate 901 is thinner than that of the gate oxide film 930 formed on inner sidewalls 941 of the trench 940 where the divots 920 are formed. This thinning phenomenon can cause device performance degradation and current leakage.

To overcome the above problems, the inventors of the present disclosure have proposed a novel method of fabricating an oxide film with uniform thickness, which will be described in detail later.

The foregoing is intended merely to aid in the understanding of the background of the present disclosure, and is not intended to mean that the present disclosure falls within the purview of the related art that is already known to those skilled in the art.

### DOCUMENTS OF RELATED ART

(Patent document 1) Korean Patent No. 10-0875350 “Production method of STI without divot”

### SUMMARY OF THE INVENTION

Accordingly, the present disclosure has been made keeping in mind the above problems occurring in the related art, and the present disclosure provides a method of fabricating an oxide film with a uniform thickness, in which when forming an oxide film in a trench for a device isolation layer and/or on a silicon substrate at a position adjacent to the trench, the silicon substrate is amorphized at positions corresponding to corners, inner sidewalls, and/or a bottom surface of the trench and then oxidized so that the oxide film in the trench and/or adjacent to the trench is formed with a substantially uniform thickness.

Another objective of the present disclosure is to provide a method of fabricating an oxide film with a uniform thickness, in which element ions with an atomic weight larger than that of silicon are used during an ion implantation process for silicon amorphization, thereby preventing ion implantation energy from becoming unnecessarily large.

Another objective of the present disclosure is to provide a method of fabricating an oxide film with a uniform thickness, in which group 13 and group 15 element ions are not used during an ion implantation process for silicon amorphization, thereby preventing the electrical characteristics of a device from being affected by implanted ions.

Another objective of the present disclosure is to provide a method of fabricating an oxide film with a uniform thickness, in which commercially available germanium or argon ions are used during an ion implantation process, thereby preventing a decrease in process efficiency.

Another objective of the present disclosure is to provide a method of fabricating an oxide film with a uniform thickness, in which an ion implantation process is performed at an ion implantation angle within a predetermined range, thereby preventing the thickness of an oxide film grown on lower sides of inner sidewalls of a trench from becoming relatively thin.

Another objective of the present disclosure is to provide a method of fabricating an oxide film with a uniform thickness, in which when forming a gate oxide film on boundaries of a device isolation layer with divots at corners thereof, a silicon substrate is amorphized and then oxidized so that a trench and/or the gate oxide film adjacent to the trench can be formed with a substantially uniform thickness.

In order to achieve the above objectives, according to one aspect of the present disclosure, there is provided method of fabricating an oxide film with a uniform thickness, the method including: forming a pad oxide film on a silicon substrate to expose and area of the substrate; forming a trench by etching the area of the substrate to a predetermined depth; locally amorphizing the substrate by performing an ion implantation process on an area of the trench; and forming an oxide film by performing an oxidation process on the substrate that is amorphized.

According to another aspect of the present disclosure, the locally amorphizing of the substrate may be performed by amorphizing the substrate at positions corresponding to boundaries of the trench.

According to another aspect of the present disclosure, the locally amorphizing of the substrate may be performed by additionally amorphizing the substrate at positions corresponding to inner sidewalls and a bottom surface of the trench.

According to another aspect of the present disclosure, the ion implantation process may be performed by implanting element ions with an atomic weight larger than an atomic weight of silicon into the substrate.

According to another aspect of the present disclosure, the ion implantation process may be performed by implanting ions of group 14 elements other than silicon into the substrate.

According to another aspect of the present disclosure, the ion implantation process may be performed by implanting tin or lead ions into the substrate.

According to another aspect of the present disclosure, the ion implantation process may be performed by implanting ions of elements other than group 13 and group 15 elements into the substrate.

According to another aspect of the present disclosure, the ion implantation process may be performed by implanting argon ions into the substrate.

According to another aspect of the present disclosure, the ion implantation process may be performed at an ion injection angle of 0° to less than 40°.

According to another aspect of the present disclosure, the method may further include: converting amorphous silicon in the substrate to polycrystalline silicon by performing a thermal process.

According to another aspect of the present disclosure, there is provided a method of fabricating an oxide film with a uniform thickness, the method including: forming a pad oxide film on a silicon substrate to expose an area of the substrate; forming a trench by etching the area of the substrate to a predetermined depth; depositing an insulating film to fill the trench; etching the pad oxide film; completing a device isolation layer having divots at corners of the device isolation layer by performing a cleaning process; locally amorphizing the substrate by performing an ion implantation process on the substrate at positions corresponding to boundaries of the trench and on inner sidewalls of the trench exposed by the divots; and forming an oxide film by performing an oxidation process on the substrate that is amorphized.

According to another aspect of the present disclosure, the ion implantation process may be performed by implanting element ions with an atomic weight larger than an atomic weight of silicon into the substrate.

According to another aspect of the present disclosure, the ion implantation process may be performed by implanting germanium ions into the substrate.

According to another aspect of the present disclosure, the ion implantation process may be performed at an ion injection angle of 0° to 45°.

According to another aspect of the present disclosure, the ion implantation process may be performed with an ion implantation energy of less than 2 KeV.

According to another aspect of the present disclosure, the ion implantation process may be performed by performing a plasma ion implantation process at a dose of 10¹³ to 5×10¹³ ion/cm².

The present disclosure has the following effects by the above configuration.

When forming the oxide film in the trench for a device isolation layer and/or on the substrate at a position adjacent to the trench, by amorphizing and then oxidizing of the silicon substrate at positions corresponding to the corners, the inner sidewalls, and/or the bottom surface of the trench, the oxide film in the trench and/or adjacent to the trench can be formed with a substantially uniform thickness.

In addition, by using the element ions with an atomic weight larger than that of silicon during the ion implantation process for silicon amorphization, it is possible to prevent the ion implantation energy from becoming unnecessarily large.

In addition, by using the group 13 and group 15 element ions during the ion implantation process for silicon amorphization, it is possible to prevent the electrical characteristics of a device from being affected by implanted ions.

In addition, by using the commercially available germanium or argon ions during the ion implantation process, it is possible to prevent a decrease in process efficiency.

In addition, by performing the ion implantation process at an ion implantation angle within a predetermined range, it is possible to prevent the thickness of the oxide film grown on the lower sides of the inner sidewalls of the trench from becoming relatively thin.

In addition, when forming the gate oxide film on the boundaries of the device isolation layer with the divots at the corners thereof, by amorphizing and then oxidizing the silicon substrate, the trench and/or the gate oxide film adjacent to the trench can be formed with a substantially uniform thickness.

Meanwhile, the effects of the present disclosure are not limited to those mentioned above, and other effects not mentioned above can be clearly understood from the following description.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a sectional view illustrating problems of the related art that occur when forming a gate oxide layer after forming a device isolation layer;

FIGS. 2 to 6 are sectional views illustrating a method of fabricating an oxide film with a uniform thickness according to a first embodiment of the present disclosure; and

FIGS. 7 to 13 are sectional views illustrating a method of fabricating an oxide film with a uniform thickness according to a second embodiment of the present disclosure.

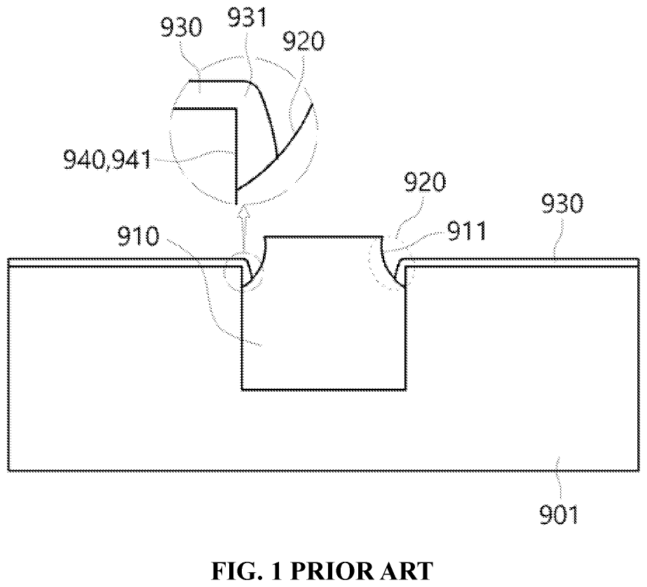

### DETAILED DESCRIPTION OF THE INVENTION

Hereinafter, exemplary embodiments of the present disclosure will be described in detail with reference to the accompanying drawings. The embodiments of the present disclosure can be modified in various forms. Therefore, the scope of the present disclosure should not be construed as being limited to the following embodiments, but should be construed on the basis of the descriptions in the appended claims. The embodiments of the present disclosure are provided for complete disclosure of the present disclosure and to fully convey the scope of the present disclosure to those ordinarily skilled in the art.

When a certain embodiment is implemented differently, a specific process order may be performed differently from the described order. For example, two consecutively described processes may be performed substantially at the same time or performed in an order opposite to the described order.

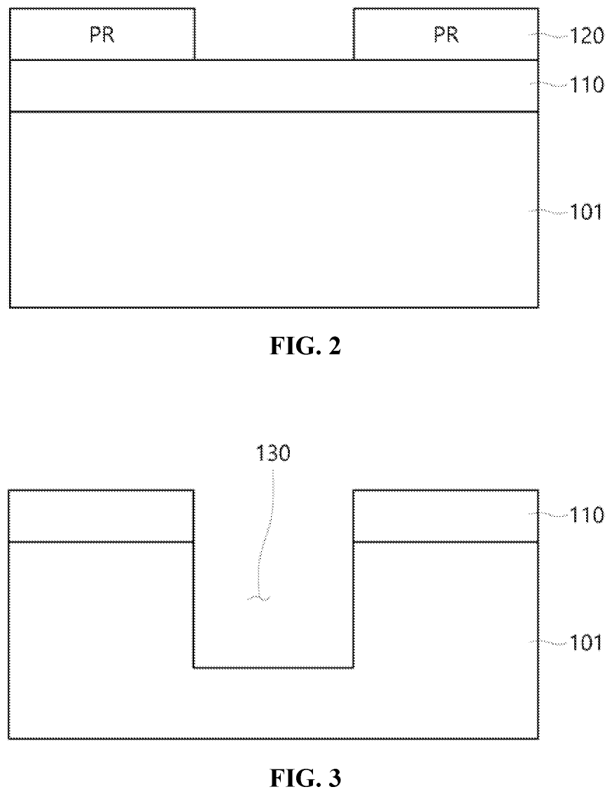

FIGS. 2 to 6 are sectional views illustrating a method of fabricating an oxide film with a uniform thickness according to a first embodiment of the present disclosure.

Hereinafter, the method of fabricating the oxide film with the uniform thickness according to the first embodiment of the present disclosure will be described in detail with reference to the accompanying drawings.

The present disclosure relates generally to a method of fabricating an oxide film with a uniform thickness. More particularly, the present disclosure relates to a method of fabricating an oxide film with a uniform thickness, in which when forming an oxide film in a trench for a device isolation layer and/or on a silicon substrate at a position adjacent to the trench, the silicon substrate is amorphized at positions corresponding to corners, inner sidewalls, and/or a bottom surface of the trench and then oxidized so that the oxide film in the trench and/or adjacent to the trench is formed with a substantially uniform thickness.

It should be understood that the fact that the oxide film is formed with a substantially “uniform thickness” means that the thickness is within the range of −10% to +10% of a target thickness. For example, in a case in which the target thickness of the oxide film is set to 100 Å (Angstrom), when the oxide film is formed with a total thickness of 90 Å to 110 Å, the oxide film is considered to be formed with a substantially uniform thickness.

Referring to FIG. 2, first, a pad oxide film 110 made of a thermal oxide film material is formed on a silicon substrate 101. Thereafter, a photoresist pattern PR 120 is formed on the pad oxide film 110, and the pad oxide film 110 is etched using the photoresist pattern PR as a mask. Then, referring to FIG. 3, an exposed side of the silicon substrate 101 is etched to a predetermined depth to form a trench 130. The etching process may be performed through, for example, a reactive ion etching (RIE) process, but the present disclosure is not limited thereto.

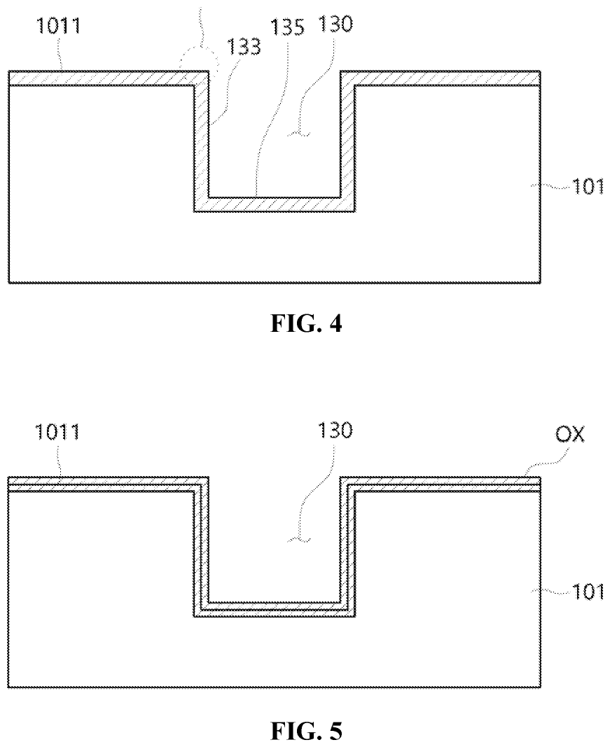

Then, referring to FIG. 4, an ion implantation process is performed on boundaries 131 of the trench 130. It should be understood that the term “boundaries 131 of the trench 130” means top ends of inner sidewalls 133 of the trench 130 and/or one side of the silicon substrate 101 adjacent to the trench 130. That is, when performing the ion implantation process on the boundaries 131 of the trench 130, it is preferable that the ion implantation process is also performed on an upper surface 1011 of the silicon substrate 101 adjacent to the boundaries 131 of the trench 130.

In addition, as illustrated in FIG. 4, during the ion implantation process, the ion implantation process may be additionally performed on the silicon substrate 101 at positions corresponding to the inner sidewalls 133 of the trench 130, and in some cases, the ion implantation process may be additionally performed on the silicon substrate 101 at a position corresponding to a bottom surface 135 of the trench 130, but the present disclosure is not limited thereto.

That is, when it is desired to form an oxide film OX with a substantially uniform thickness on the silicon substrate 101 at positions corresponding to the boundaries 131 of the trench 130, the ion implantation process may be performed on the silicon substrate 101 at positions corresponding to the boundaries 131 of the trench 130. When it is desired to form an oxide film OX with a substantially uniform thickness on the inner sidewalls 133 and the bottom surface 135 of the trench 130, the ion implantation process may also be performed on the silicon substrate 101 at positions corresponding to the inner sidewalls 133 and the bottom surface 135 of the trench 130.

The ion implantation process is a process of amorphizing the silicon substrate 101 in order to ensure that the oxide film OX has a substantially uniform vertical thickness during a subsequent oxidation process. Silicon (Si) generally has a crystalline state in which the atomic arrangement is regular, so when the oxidation process is performed on the silicon substrate 101, the thickness of the grown oxide film OX becomes substantially non-uniform because the number of silicon atoms varies depending on the crystal direction of the substrate 101. In the embodiment of the present disclosure, in order to prevent the above problem, the ion implantation process is performed to locally form amorphous silicon so that the arrangement of silicon atoms is disordered, and then the oxidation process is performed.

During the ion implantation process, it is preferable that ions of an element with a larger atomic weight than silicon are implanted into the silicon substrate 101. On the contrary, when ions of an element with a smaller atomic weight than silicon are implanted into the silicon substrate 101, a problem may occur in that ion implantation energy becomes unnecessarily large.

In addition, during the ion implantation process, it is preferable to use group 14 elements excluding silicon. As described above, since the use of element ions with an atomic weight larger than silicon is preferable, among group 14 elements, germanium (Ge), tin (Sn), or lead (Pb) ions may be used.

Alternatively, ions of elements other than group 14 elements may be used. For example, ions of any element other than group 13 and group 15 elements that can electrically affect a device, such as N-type or P-type, may be used. More specifically, argon (Ar) ions of group 18 may be used.

In addition, during the ion implantation process, it is preferable to use commercially available germanium (Ge) or argon (Ar) ions, but the present disclosure is not limited thereto.

In addition, when the oxide film OX is formed with a target thickness of 100 Å, the ion implantation energy is preferably less than 2 KeV and a plasma ion implantation process is preferably performed at a dose of 10¹³ to 5×10¹³ ion/cm². In addition, during the ion implantation process, an ion injection angle is preferably 0° to 45°, and more preferably greater than 0° to less than 40°. When the ion implantation angle is 0°, the thickness of the oxide film OX grown on lower sides of the inner sidewalls 133 of the trench 130 may become relatively thin, so it is preferable that the ion implantation angle is a predetermined angle.

Referring to FIG. 5, after the ion implantation process is completed, an oxidation process is performed to form an oxide film OX. As described above, the oxide film OX is not only formed on the silicon substrate 101 at positions corresponding to the boundaries 131 of the trench 130, but also on the silicon substrate 101 at positions corresponding to the inner sidewalls 133 and the bottom surface 135 of the trench 130. As described above, the silicon substrate 101 is locally amorphized and then oxidized so that the oxide film OX is grown to a substantially uniform thickness.

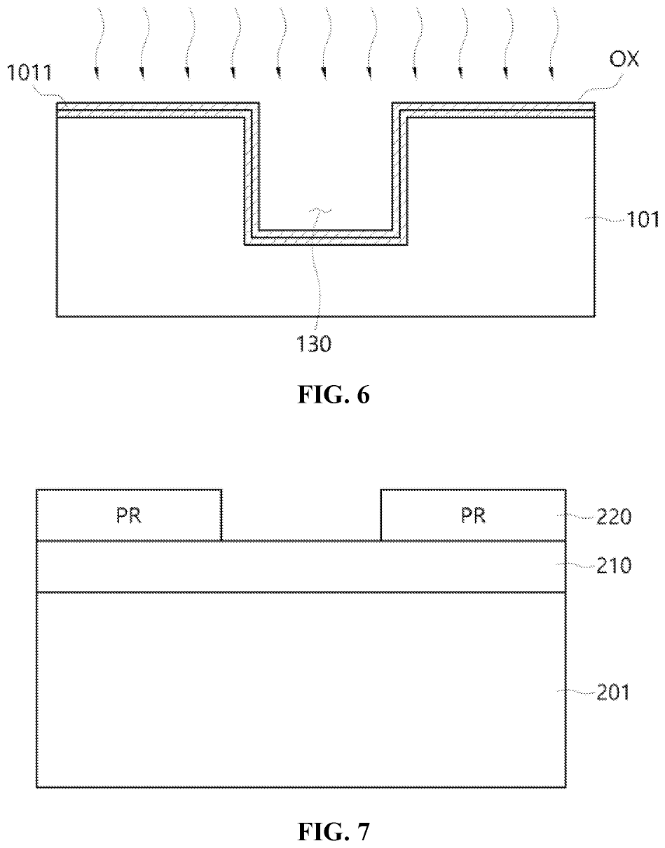

Referring to FIG. 6, after the oxide film OX is formed, a thermal process is performed under predetermined conditions to convert the amorphous silicon in the substrate 101 into polycrystalline silicon.

FIGS. 7 to 13 are sectional views illustrating a method of fabricating an oxide film with a uniform thickness according to a second embodiment of the present disclosure.

Hereinafter, the method of fabricating the oxide film with the uniform thickness according to the second embodiment of the present disclosure will be described in detail with reference to the accompanying drawings. The second embodiment differs from the first embodiment in that an additional oxide film is formed after depositing an insulating film in a trench. In this case, the oxide film may be, for example, a gate oxide film, but the present disclosure is not limited thereto. In addition, in the second embodiment, description of content that overlaps with the first embodiment will be omitted for convenience of explanation.

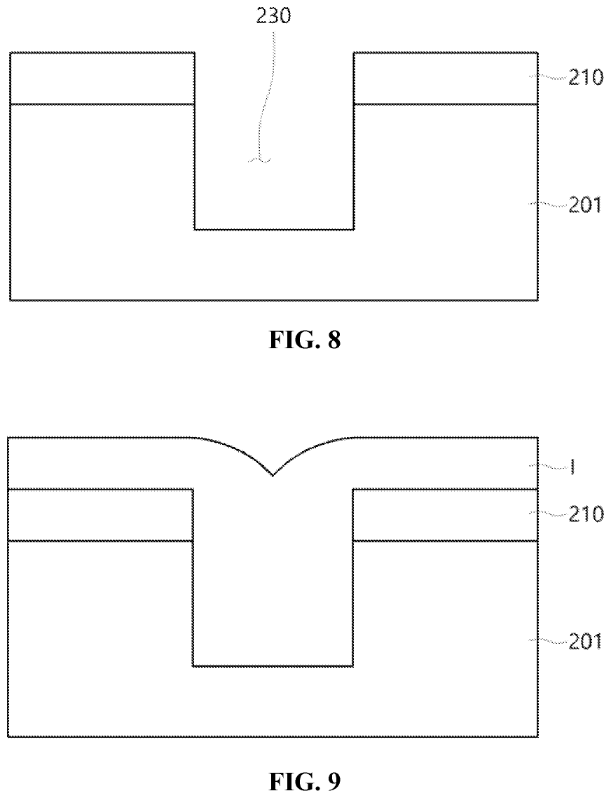

Referring to FIG. 7, first, a pad oxide film 210 made of a thermal oxide film material is formed on a silicon substrate 201. Thereafter, a photoresist pattern PR 220 is formed on the pad oxide film 210, and the pad oxide film 210 is etched using the photoresist pattern PR as a mask. Then, referring to FIG. 8, an exposed side of the silicon substrate 201 is etched to a predetermined depth to form a trench 230.

Then, referring to FIG. 9, an insulating film I is deposited on the silicon substrate 201 or the pad oxide film 210 to fill the trench 230. The insulating film I may be, for example, a tetra-ethyl ortho-silicate (TEOS) film, but the present disclosure is not limited thereto.

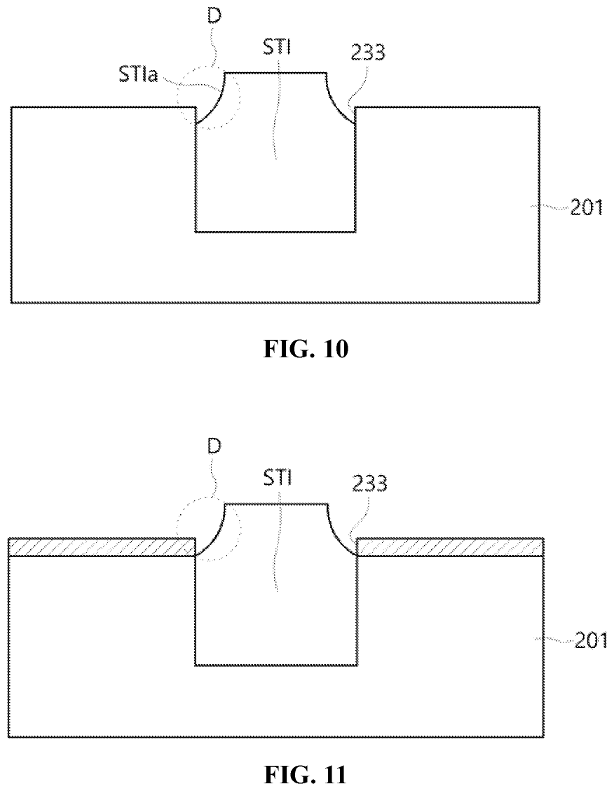

Then, referring to FIG. 10, a CMP process and then an etching process for the pad oxide film 210 are performed, and a cleaning process is performed to complete a device isolation layer STI. Here, the etching process may be, for example, a wet etching process. As described above, during the cleaning process, edges STIa of the device isolation layer STI may be excessively etched, resulting in divots D.

In this state in which the divots D are generated, when forming a gate oxide film OX on the silicon substrate 201 and on inner sidewalls 233 of the trench 230 where the divots D are formed, a thinning phenomenon in which the thickness of the gate oxide film OX′ becomes uneven occurs. In detail, the thickness of the gate oxide film OX?formed on the silicon substrate 201 at a position adjacent to the trench 230 is thinner than that of the gate oxide film OX′ formed on the inner sidewalls 233 of the trench 230 where the divots D are formed. When a gate electrode (not illustrated) is formed on the gate oxide film OX′ in this state, there is a possibility that the oxide film OX′ may be deteriorated due to an electric field being concentrated at corners of the gate oxide film OX when a device is driven.

Therefore, the gate oxide film OX′ needs to be formed to have a substantially uniform thickness. However, as described above, it should be noted that the oxide film OX′ is not limited to a “gate oxide film”.

Referring to FIG. 11, in order to form the oxide film OX to a substantially uniform thickness, an ion implantation process is performed on boundaries of the trench 230 to locally amorphize silicon in the substrate 201. The ion implantation process may also be performed on the substrate 201 at positions corresponding to the inner sidewalls 233 of the trench 230 where the divots D are formed. Since the ion implantation process applied at this time is substantially the same as the ion implantation process in the first embodiment, detailed description thereof will be omitted.

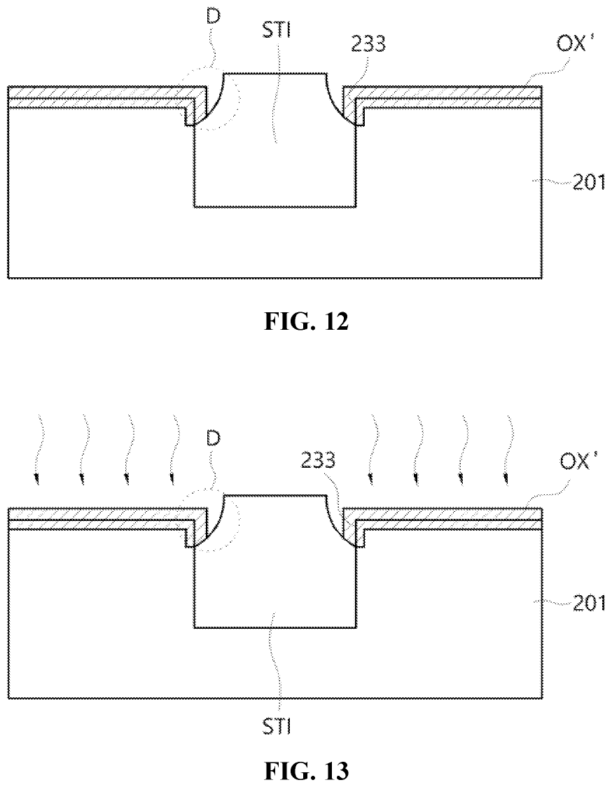

Then, referring to FIG. 12, after the ion implantation process is completed, an oxidation process is performed to form an oxide film OX′. As a result, the oxide film OX′ having a substantially uniform thickness is formed on the silicon substrate 201 at a position adjacent to the trench 230 and on the inner sidewalls 233 of the trench 230.

Referring to FIG. 13, after the oxide film OX′ is formed, a thermal process is performed under predetermined conditions to convert the amorphous silicon in the substrate 201 into polycrystalline silicon.

The foregoing detailed description may be merely an example of the present disclosure. Also, the inventive concept is explained by describing the preferred embodiments and will be used through various combinations, modifications, and environments. That is, the inventive concept may be amended or modified without departing from the scope of the technical idea and/or knowledge in the art. The foregoing embodiments are for illustrating the best mode for implementing the technical idea of the present disclosure, and various modifications may be made therein according to specific application fields and uses of the present disclosure. Therefore, the foregoing detailed description of the present disclosure is not intended to limit the inventive concept to the disclosed embodiments.

What is claimed is:

1. A method of fabricating an oxide film with a uniform thickness, the method comprising:
forming a pad oxide film on a silicon substrate to expose an area of the substrate;
forming a trench by etching the area of the substrate to a predetermined depth;
locally amorphizing the substrate by performing an ion implantation process on an area of the trench; and
forming an oxide film by performing an oxidation process on the substrate that is amorphized.

2. The method of claim 1, wherein the locally amorphizing of the substrate is performed by amorphizing the substrate at positions corresponding to boundaries of the trench.

3. The method of claim 2, wherein the locally amorphizing of the substrate is performed by additionally amorphizing the substrate at positions corresponding to inner sidewalls and a bottom surface of the trench.

4. The method of claim 3, wherein the ion implantation process is performed by implanting element ions with an atomic weight larger than an atomic weight of silicon into the substrate.

5. The method of claim 4, wherein the ion implantation process is performed by implanting ions of group 14 elements other than silicon into the substrate.

6. The method of claim 5, wherein the ion implantation process is performed by implanting tin or lead ions into the substrate.

7. The method of claim 4, wherein the ion implantation process is performed by implanting ions of elements other than group 13 and group 15 elements into the substrate.

8. The method of claim 7, wherein the ion implantation process is performed by implanting argon ions into the substrate.

9. The method of claim 4, wherein the ion implantation process is performed at an ion injection angle of 0° to less than 40°.

10. The method of claim 4, further comprising:
converting amorphous silicon in the substrate to polycrystalline silicon by performing a thermal process.

11. A method of fabricating an oxide film with a uniform thickness, the method comprising:
forming a pad oxide film on a silicon substrate to expose an area of the substrate;
forming a trench by etching the area of the substrate to a predetermined depth;
depositing an insulating film to fill the trench;
etching the pad oxide film;
completing a device isolation layer having divots at corners of the device isolation layer by performing a cleaning process;
locally amorphizing the substrate by performing an ion implantation process on the substrate at positions corresponding to boundaries of the trench and on inner sidewalls of the trench exposed by the divots; and
forming an oxide film by performing an oxidation process on the substrate that is amorphized.

12. The method of claim 11, wherein the ion implantation process is performed by implanting element ions with an atomic weight larger than an atomic weight of silicon into the substrate.

13. The method of claim 11, wherein the ion implantation process is performed by implanting germanium ions into the substrate.

14. The method of claim 13, wherein the ion implantation process is performed at an ion injection angle of 0° to 45°.

15. The method of claim 14, wherein the ion implantation process is performed with an ion implantation energy of less than 2 KeV.

16. The method of claim 14, wherein the ion implantation process is performed by performing a plasma ion implantation process at a dose of 10¹³ to 5×10¹³ ion/cm².
